(19) United States
(12) Patent Application Publication
(10) Pub. No.: US 2024/0321938 A1
(43) Pub. Date: Sep. 26, 2024

(54) SEMICONDUCTOR DEVICE

(71) Applicant: SAMSUNG ELECTRONICS CO., LTD., SUWON-SI (KR)

(72) Inventors: Cheoljin Cho, Suwon-si (KR); Yukyung Shin, Suwon-si (KR); Jieun Lee, Suwon-si (KR); Hanjin Lim, Suwon-si (KR); Changhwa Jung, Suwon-si (KR); Jayun Choi, Suwon-si (KR)

(21) Appl. No.: 18/591,310

(22) Filed: Feb. 29, 2024

(30) Foreign Application Priority Data
Mar. 21, 2023 (KR) 10-2023-0036924

(51) Int. Cl. H10B 12/00

(52) U.S. Cl. CPC H01L 28/55; H10B 12/482; H10B 12/488

(57) ABSTRACT

A semiconductor device includes a lower electrode disposed on a substrate; a dielectric layer covering the lower electrode; and an upper electrode spaced apart from the lower electrode. The dielectric layer is disposed between the upper electrode and the lower electrode. A thickness of the dielectric layer is less than or equal to 6 nm, and a grain size in the dielectric layer is between 3 nm and 30 nm.

### CROSS-REFERENCE TO RELATED APPLICATION

The application claims priority under 35 U.S.C. § 119 to Korean Patent Application Nos. 10-2023-0036924, filed on Mar. 21, 2023, in the Korean Intellectual Property Office, the disclosure of which is incorporated by reference herein in its entirety.

### BACKGROUND

Embodiments of the present disclosure relate to a semiconductor device, and more particularly, to a semiconductor device including a capacitor.

As a semiconductor memory device becomes more highly integrated, individual circuit patterns are increasingly miniaturized, allowing for accommodation of more semiconductor memory devices within the same area. As the degree of integration of the semiconductor memory device increases, design rules for components of the semiconductor memory device become stricter.

In a highly scaled semiconductor memory device, a process of forming a capacitor becomes more complicated and challenging. In miniaturized semiconductor devices, obtaining the target capacitance using conventional capacitor structures poses significant limitations.

### SUMMARY

Embodiments of the present disclosure provide a semiconductor device having a capacitor with increased capacitance.

The inventive concept also provides a semiconductor device having a capacitor with increased performance and reliability.

Embodiments of the present disclosure are not limited to serving the aforementioned objectives, and other objectives not mentioned can be clearly understood by a person skilled in the art from the following description.

According to embodiments of the present disclosure, a semiconductor device comprises a lower electrode disposed on a substrate; a dielectric layer covering the lower electrode; and an upper electrode spaced apart from the lower electrode. The dielectric layer is disposed between the upper electrode and the lower electrode. A thickness of the dielectric layer is less than or equal to 6 nm, and a grain size in the dielectric layer is between 3 nm and 30 nm.

According to embodiments of the present disclosure, a semiconductor device includes a lower electrode disposed on a substrate; a dielectric layer covering the lower electrode; and an upper electrode spaced apart from the lower electrode, wherein the dielectric layer is disposed between the upper electrode and the lower electrode. The dielectric layer is deposited to an initial thickness that is greater than 6 nm and less than or equal to 15 nm and is etched to a final thickness that is less than or equal to 6 nm.

According to embodiments of the present disclosure, a semiconductor device includes an active region defined by a device isolation layer in a substrate; word lines extending in a first horizontal direction; bit lines extending in a second horizontal direction perpendicular to the first horizontal direction; and a capacitor structure electrically connected to the active region at a vertical level that is higher than the bit lines. The capacitor structure comprises a lower electrode extending in a vertical direction perpendicular to the first horizontal direction and the second horizontal direction; a dielectric layer covering the lower electrode; and an upper electrode spaced apart from the lower electrode, where the dielectric layer is disposed between the upper electrode and the lower electrode, a thickness of the dielectric layer is less than or equal to 6 nm, and a grain size in the dielectric layer is between 3 nm and 15 nm.

According to embodiments of the present disclosure, a method of manufacturing a semiconductor device includes providing a lower electrode on a substrate; depositing a dielectric layer on the lower electrode to a first thickness; crystallizing the dielectric layer at a temperature less than 450° C.; etching the dielectric layer to a second thickness less than the first thickness; providing an upper electrode spaced apart from the lower electrode, where the dielectric layer is disposed between the upper electrode and the lower electrode.

### BRIEF DESCRIPTION OF THE DRAWINGS

FIG. 1 is a schematic plan layout diagram for describing components of a memory cell array region of a semiconductor device according to embodiments;

FIG. 2 is a plan view illustrating a configuration of the semiconductor device illustrated in FIG. 1;

FIG. 3 is a cross-sectional view schematically illustrating a configuration of the semiconductor device taken along a line X-X′ of FIG. 2;

FIG. 4 is a detailed cross-sectional view of a region EX1 of FIG. 3;

FIGS. 5 and 6 illustrate a semiconductor device according to embodiments;

FIG. 7 is a graph illustrating free energy according to thicknesses of a crystalline thin layer and an amorphous thin layer to describe a semiconductor device according to embodiments;

FIG. 8 is a detailed cross-sectional view for describing a semiconductor device according to embodiments;

FIGS. 9A, 9B, and 9C illustrate a semiconductor device according to embodiments;

FIGS. 10, 11, 12, 13, and 14 are flowcharts for describing a method of manufacturing a semiconductor device according to embodiments; and

FIGS. 15A, 15B, 15C, 15D, 15E, 15F, and 15G are cross-sectional views for describing a method of manufacturing a semiconductor device according to embodiments.

FIG. 16 is a flowchart showing a method for manufacturing a semiconductor device.

### DETAILED DESCRIPTION

In semiconductor processing, accurate control over the thickness and structure of dielectric layers is important. Conventionally, dielectric layers were directly deposited to their desired target thickness, for example, 7 nm or less. This method aimed to produce crystalline grains with a size less than about 3.5 nm. However, this approach presented limitations in achieving consistent and desirable material properties.

Embodiments of the present disclosure address these challenges by using a method that involves depositing a dielectric layer beyond a conventional target thickness, employing low-temperature crystallization to modify the structure, and performing atomic layer etching to achieve the desired thickness. More specifically, instead of directly depositing the dielectric layer to the target thickness, the method involves initially depositing the dielectric layer to a thickness that ranges between 7 nm to 15 nm, notably more than the target thickness. Subsequent to this step, an unconventional low-temperature crystallization process is applied. The low temperature may range between 300-450° C. Following this low-temperature crystallization process, atomic layer etching is employed to trim down the dielectric layer to its target thickness, resulting in crystalline grains that are at least 3.5 nm and no larger than 30 nm in size. Accordingly, embodiments of the present disclosure provide an approach to dielectric layer fabrication with increased semiconductor device performance.

In order to sufficiently understand the configuration and effect of the embodiments of the present disclosure, embodiments will be described with reference to the accompanying drawings. However, the embodiments of the present disclosure are not limited to the embodiments disclosed herein, but may be implemented in a variety of forms. The description of the present embodiments is provided to completely inform the scope of the embodiments of the present disclosure to a person having ordinary skill in the art to which the embodiments of the present disclosure are directed to. In the accompanying drawings, for convenience of description, the sizes of components are greater than actual sizes, and the ratio of each component may be exaggerated or reduced.

Unless otherwise provided, the terms used in some embodiments may be interpreted as having a commonly known meaning to those skilled in the art.

Hereinafter, embodiments will be described in detail with reference to the accompanying drawings.

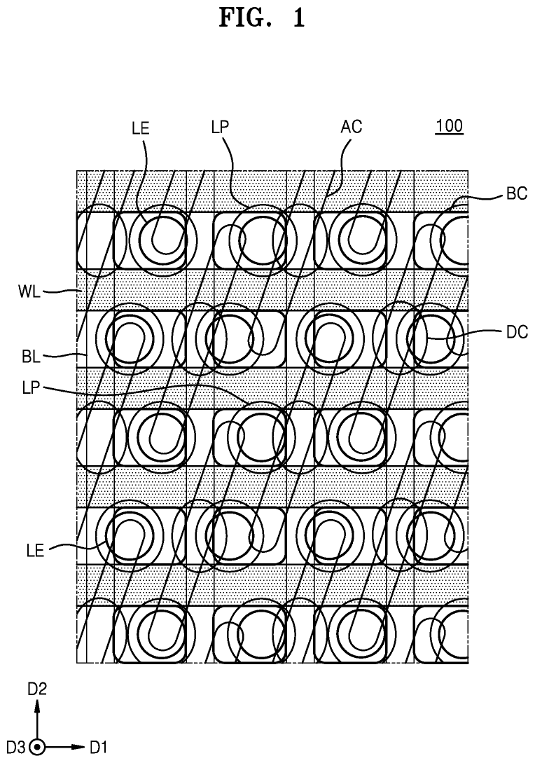

FIG. 1 is a schematic plan layout diagram for describing components of a memory cell array region of a semiconductor device 100 according to embodiments.

Referring to FIG. 1, the semiconductor device 100 may include a plurality of active regions AC disposed on a plane formed by a first direction D1 and a second direction D2. The plurality of active regions AC may extend horizontally in a diagonal direction with respect to the first direction D1 and the second direction D2 of the plane. A plurality of word lines WL may extend in a direction parallel to each other in the first direction D1, crossing the plurality of active regions AC. A plurality of bit lines BL may extend in a direction parallel to each other in the second direction D2 crossing the first direction D1 on the plurality of word lines WL. Each of the plurality of bit lines BL may be connected to each of the active regions AC via a direct contact DC.

A plurality of buried contacts BC may be disposed between two bit lines BL among the plurality of bit lines BL. In some examples, the two bit lines BL may be adjacent to each other. A plurality of conductive landing pads LP may be disposed on the plurality of buried contacts BC. The plurality of conductive landing pads LP may be disposed so that at least a portion of the plurality of conductive landing pads LP overlaps each buried contact BC. A plurality of lower electrodes LE may be spaced apart from each other on the plurality of conductive landing pads LP. The plurality of lower electrodes LE may be connected to the plurality of active regions AC through the plurality of buried contacts BC and the plurality of conductive landing pads LP.

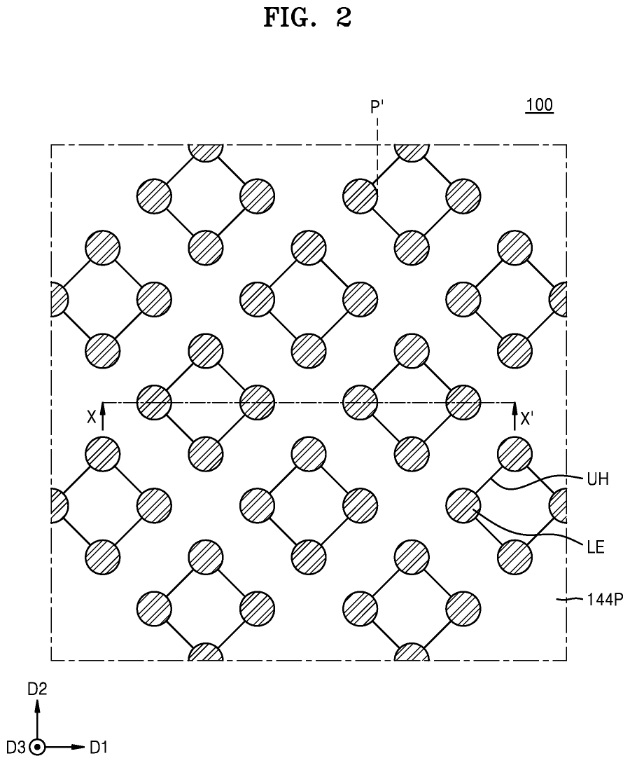

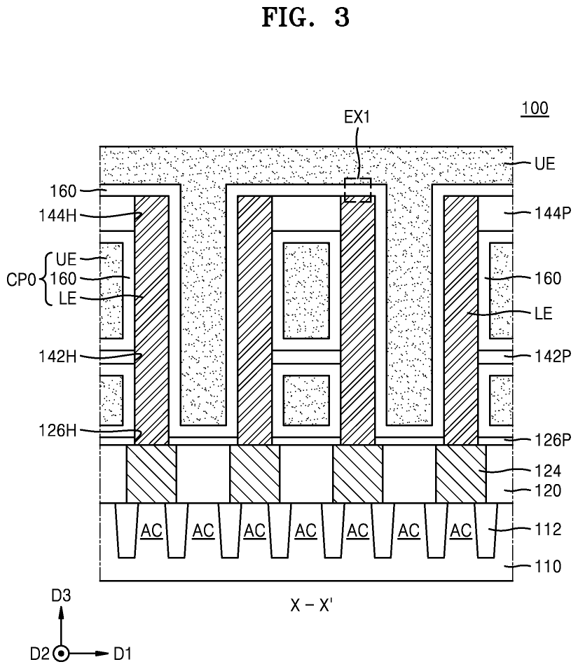

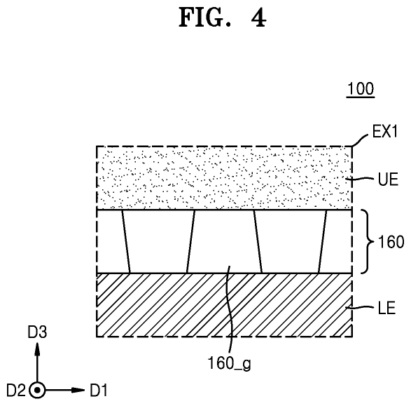

FIG. 2 is a plan view illustrating a configuration of the semiconductor device 100 in FIG. 1. FIG. 3 is a cross-sectional view schematically illustrating a configuration of the semiconductor device taken along a line X-X′ in FIG. 2. FIG. 4 is a detailed cross-sectional view of a region EX1 illustrated in FIG. 3.

According to some embodiments, semiconductor device includes a lower electrode disposed on a substrate, a dielectric layer covering the lower electrode, and an upper electrode spaced apart from the lower electrode. In some cases, the dielectric layer is disposed between the upper electrode and the lower electrode. In some cases, the thickness of the dielectric layer is less than or equal to 6 nm, and the grain size in the dielectric layer is between 3 nm and 30 nm. Referring to FIGS. 2 and 3, the semiconductor device 100 may include a substrate 110 including a plurality of active regions AC, and a lower structure 120 formed on the substrate 110. A plurality of conductive regions 124 may pass through the lower structure 120 and may be connected to the plurality of active regions AC.

The substrate 110 may include a semiconductor material such as silicon (Si) or germanium (Ge), or a compound semiconductor such as silicon carbide (SiC), gallium arsenide (GaAs), indium arsenide (InAs), and indium phosphorous (InP). The substrate 110 may include a semiconductor substrate, at least one insulating layer formed on the semiconductor substrate. In some cases, the substrate 110 may include structures including at least one conductive region. The conductive region may include a well doped with impurities. In some cases, the conductive region may include a structure doped with impurities. A device isolation layer 112 defining the plurality of active regions AC may be formed on the substrate 110. Defining refers to the process of delineating, setting boundaries, or specifying the area or shape of the region. For example, the active region AC on the substrate 110 is defined by the device isolation layer 112 when the device isolation layer 112 outlines the boundaries of the active region AC, indicating where the active region AC is located or how it is shaped on the substrate 110. The device isolation layer 112 may include an oxide layer, a nitride layer, or a combination thereof. In some embodiments, the device isolation layer 112 may have multiple structures including a shallow trench isolation (STI) structure, and the like.

In some embodiments, the lower structure 120 may include an insulating layer including a silicon oxide layer, a silicon nitride layer, or a combination thereof. In some embodiments, the lower structure 120 may include multiple conductive regions, for example, a wiring layer, a contact plug, a transistor, and the like, and an insulating layer separating the multiple conductive regions. In some examples, the insulating layer insulates the multiple conductive regions from one another. The plurality of conductive regions 124 may include polysilicon, conductive metal nitride, metal silicide, or a combination thereof. The lower structure 120 may include the plurality of bit lines BL described above with reference to FIG. 1. The plurality of conductive regions 124 may include the buried contact BC and the conductive landing pad LP described above with reference to FIG. 1.

An insulating pattern 126P having a plurality of openings 126H overlapping the plurality of conductive regions 124 in a vertical direction D3 may be disposed on the lower structure 120 and the plurality of conductive regions 124. The insulating pattern 126P may include silicon nitride (SiN), silicon carbon nitride (SiCN), silicon boron nitride (SiBN), or a combination thereof. As used herein, the terms “SiN”, “SiCN”, and “SiBN” refer to materials including the corresponding elements, and are not a chemical formula that represents a stoichiometric relationship.

A plurality of capacitors CP0 may be disposed in the plurality of conductive regions 124. Each of the plurality of capacitors CP0 may include a lower electrode LE extending in the direction D3, perpendicular to an upper surface of the substrate 110. A sidewall of the lower electrode LE may be surrounded by supporters 142P and 144P and supporting the lower electrode LE, a dielectric layer 160 disposed on the lower electrode LE and the supporters 142P and 144P, and an upper electrode UE covering the dielectric layer 160 and spaced apart from the lower electrode LE. In some cases, the dielectric layer 160 is disposed between the dielectric layer 160 and the lower electrode LE.

The insulating pattern 126P may be disposed adjacent to a lower end portion of each of the plurality of lower electrodes LE. Each of the plurality of lower electrodes LE may have a pillar shape extending in a direction away from the substrate 110 in the vertical direction D3 through the opening 126H of the insulating pattern 126P from the upper surface of the conductive region 124. In the diagram, a case in which each of the plurality of lower electrodes LE has a pillar shape has been described as an example. However, the technical spirit of the embodiments of the present disclosure is not limited thereto. For example, each of the plurality of lower electrodes LE may have a cylindrical cross-sectional structure in which a cup shape or a bottom portion of each of the plurality of lower electrodes LE is closed.

The plurality of lower electrodes LE may be supported by a lower supporter 142P and an upper supporter 144P. The plurality of lower electrodes LE and the upper electrode UE may face each other where the dielectric layer 160 is disposed between the plurality of lower electrodes LE and the upper electrode UE. The dielectric layer 160 may cover the lower electrode LE, the lower supporter 142P, and the upper supporter 144P.

The upper supporter 144P may surround an upper end portion of each of the plurality of lower electrodes LE and may extend in a direction parallel to the substrate 110. A plurality of holes 144H through which the plurality of lower electrodes LE pass, may be formed in the upper supporter 144P. An inner sidewall of each of the plurality of holes 144H formed in the upper supporter 144P may be in contact with an outer sidewall of the lower electrode LE. An upper surface of each of the plurality of lower electrodes LE and an upper surface of the upper support 144P may be on the same plane.

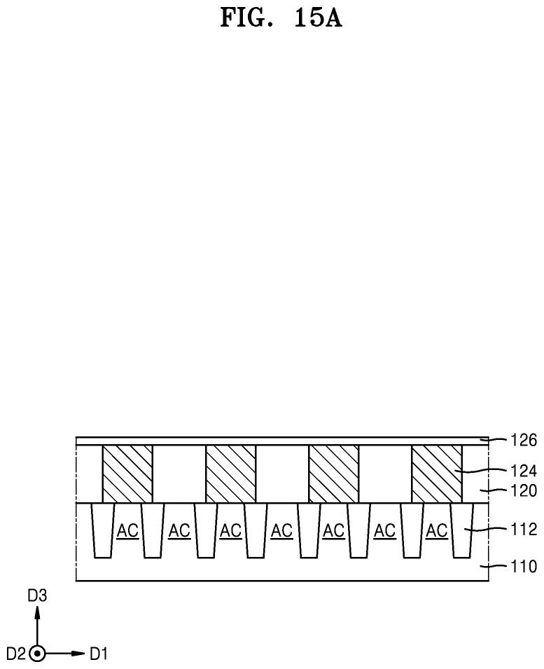

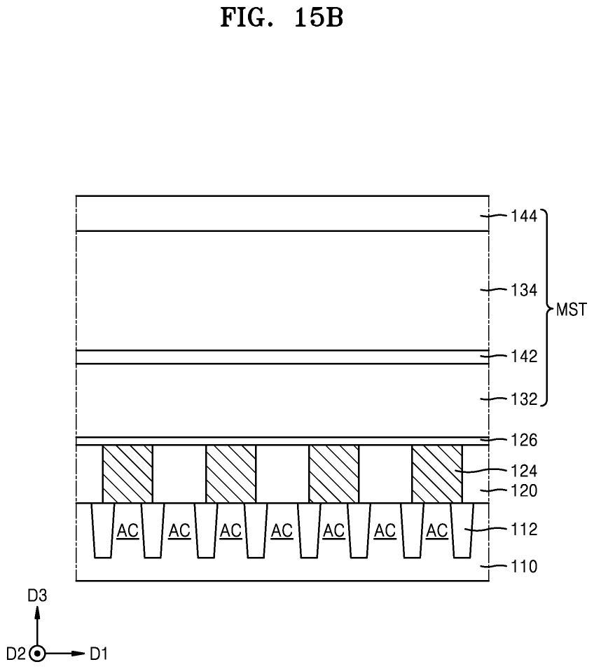

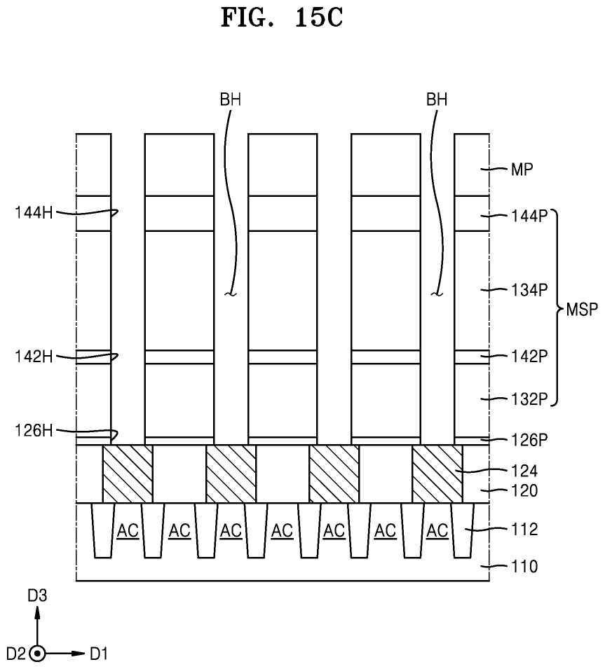

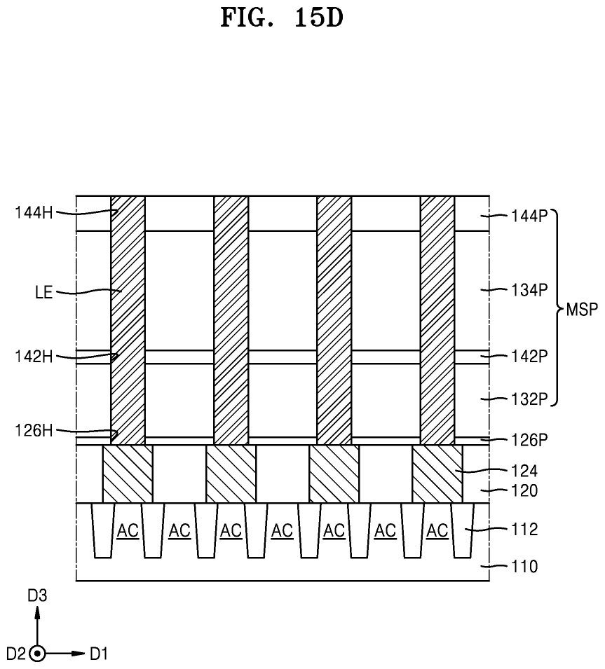

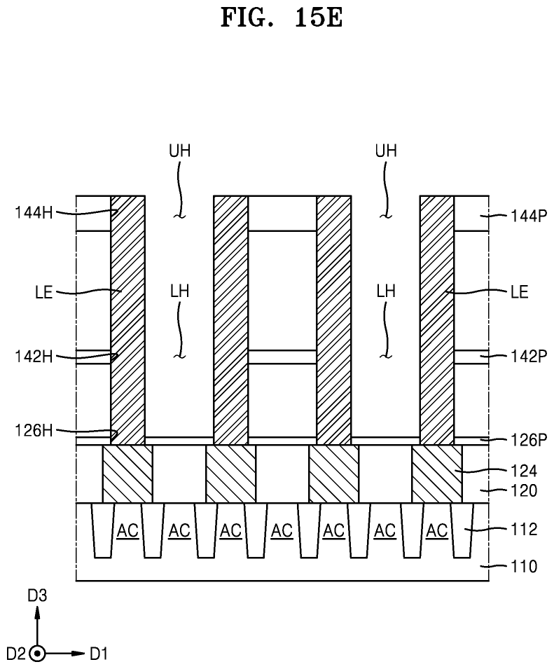

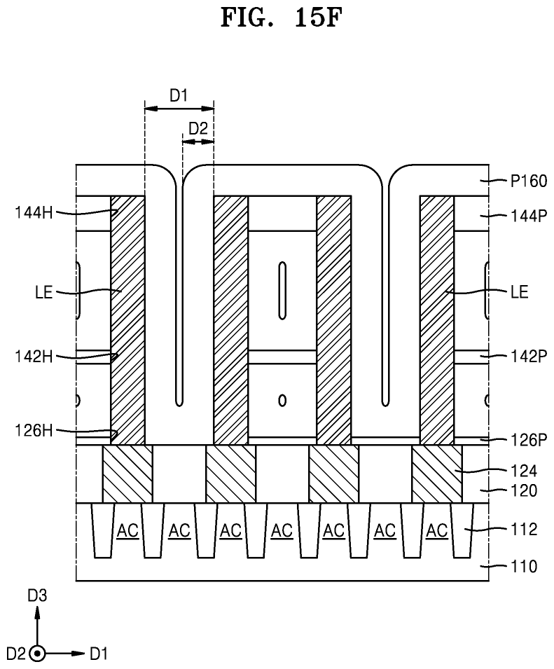

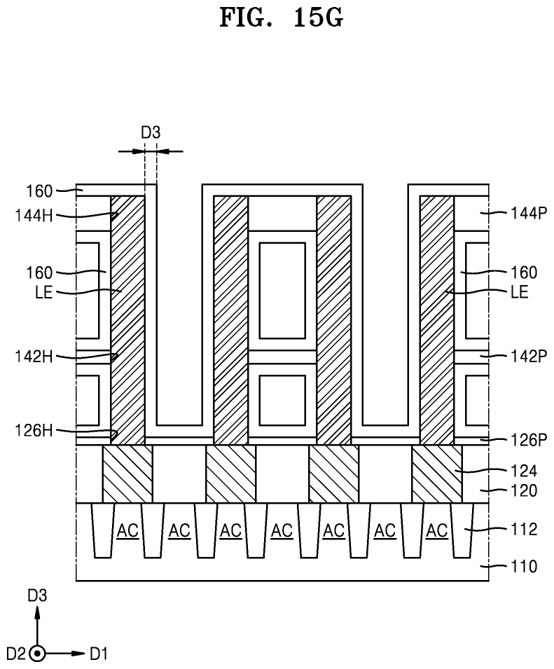

The lower supporter 142P may extend in a direction parallel to the substrate 110 between the substrate 110 and the upper supporter 144P and may be in contact with an outer sidewall of the plurality of lower electrodes LE. A plurality of holes 142H through which the plurality of lower electrodes LE pass, and a plurality of lower holes LH (see FIG. 15E) may be formed in the lower supporter 142P. The plurality of lower electrodes LE may pass through the plurality of holes 144H formed in the upper supporter 144P and the plurality of holes 142H formed in the lower supporter 142P and may extend in the vertical direction D3.

FIG. 2 illustrates a planar structure of the upper supporter 144P and each of the plurality of lower electrodes LE. As illustrated in FIG. 2, a plurality of upper holes UH may be formed in the upper supporter 144P. The configuration of a case in which a planar shape of each of the plurality of upper holes UH is a schematic rhombus-shaped planar shape in which four adjacent lower electrodes LE form a vertex, is illustrated in FIG. 2. However, a planar shape of each of the plurality of upper holes UH is not limited to that illustrated in FIG. 2, and multiple modifications and changes may be performed within the scope of embodiments of the present disclosure. The plurality of lower electrodes LE may include portions that protrude up to a first point P′ toward the center of the upper holes UH. A plurality of lower holes LH (see FIG. 15E) having a planar shape corresponding to a planar shape of the plurality of upper holes UH may be formed in the lower supporter 142P.

Each of the lower supporter 142P and the upper supporter 144P may include a SiN layer, a SiCN layer, a silicon boron nitride (SiBN) layer, or a combination thereof. In some embodiments, the lower supporter 142P and the upper supporter 144P may include the same material. In another embodiments, the lower supporter 142P and the upper supporter 144P may include different materials. In an example, each of the lower supporter 142P and the upper supporter 144P may include SiCN. In another example, the lower supporter 142P may include SiCN, and the upper supporter 144P may include SiBN. However, the technical spirit of the embodiments of the present disclosure is not limited to the illustrated materials.

The lower electrode LE may include a metal-containing layer including a first metal. The upper electrode UE may face the lower electrode LE. In some cases, the dielectric layer 160 is disposed between the upper electrode UE and the lower electrode LE. In some embodiments, the upper electrode UE may include the same material as that of the first metal. In another embodiment, the upper electrode UE may include a different material from that of the first metal.

The lower electrode LE and the upper electrode UE may include a metal layer, a conductive metal oxide layer, a conductive metal nitride layer, a conductive metal oxynitride layer, or a combination thereof. In some embodiments, the lower electrode LE and the upper electrode UE may include titanium (Ti), Ti oxide, Ti nitride, Ti oxynitride, niobium (Nb), Nb oxide, Nb nitride, Nb oxynitride, cobalt (Co), Co oxide, Co nitride, Co oxynitride, tin (Sn), Sn oxide, Sn nitride, Sn oxynitride, or a combination thereof. For example, each of the lower electrode LE and the upper electrode UE may include NbN, TiN, CON, SnO₂, or a combination thereof. In other embodiments, each of the lower electrode LE and the upper electrode UE may include tantalum nitride (TaN), titanium aluminum nitride (TiAlN), tantalum aluminum nitride (TaAlN), tungsten (W), ruthenium (Ru), RuO₂, SrRuO₃, iridium (Ir), IrO₂, platinum (Pt), platinum oxide (PtO), SRO(SrRuO₃), BSRO((Ba,Sr)RuO₃), CRO(CaRuO₃), LSCO((La,Sr)CoO₃), or a combination thereof. However, material of each of the lower electrode LE and the upper electrode UE is not limited thereto.

Each of a horizontal dimension of the lower electrode LE and a horizontal direction and/or a vertical dimension of the upper electrode UE may be about 1 nm to about 20 nm. Alternatively, in some embodiments, the horizontal dimension of the lower electrode LE and the horizontal direction and/or the vertical dimension of the upper electrode UE may be greater than or equal to about 20 nm. In some embodiments, the horizontal dimension of the lower electrode LE may be greater than the horizontal dimension and/or the vertical dimension of the upper electrode UE. However, embodiments are not limited thereto, and the horizontal dimension of the lower electrode LE may be substantially the same as or less than the horizontal dimension and/or the vertical dimension of the upper electrode UE.

The dielectric layer 160 may include a high-k dielectric layer. The “high-k dielectric layer” refers to a dielectric layer having a higher dielectric constant than that of a silicon oxide layer. In some embodiments, the dielectric layer 160 may include a metal oxide material including at least one metal selected from the group consisting of hafnium (Hf), zirconium (Zr), Al, Nb, cerium (Ce), lanthanum (La), Ta, and Ti. In some embodiments, the dielectric layer 160 may have a single layer structure including one high-k dielectric layer. In other embodiments, the dielectric layer 160 may have a multi-layer structure including a plurality of high-k dielectric layer. The high-k dielectric layer may include HfO₂, ZrO₂, Al₂O₃, La₂O₃, Ta₂O₃, Nb₂O₅, CeO₂, TiO₂, GeO₂, or a combination thereof, and embodiments are not limited thereto.

In some embodiments, the dielectric layer 160 may include at least one of a ferroelectric material layer, a semi-ferroelectric material layer, and a paraelectric material layer. For example, the dielectric layer 160 may include HfZrO₂, ZrO₂, PbTiO₃, AgNbO₃, HfO₂, ZrO₂, TiO₂, Ta₂O₃, VO₂, AlO₂, SiO₂, SrTiO₃ BaTiO₃, BiFcO₃, or a combination thereof. However, embodiments are not limited thereto.

In some embodiments, the thickness of the dielectric layer 160 may be about 6 nm or less. For example, the thickness of the dielectric layer 160 may be about 6 nm.

Referring to FIG. 4, the dielectric layer 160 may include a plurality of grains 160_g. In some embodiments, the grain size of grains 160_g may be about 3 nm to about 30 nm. For example, the grain size of grains 160_g may be about 3 nm to about 15 nm. When the size of the grain 160_g is about 3 nm to about 6 nm, the size of the grain 160_g may be less than or equal to the thickness of the dielectric layer 160. When the size of the grain 160_g is about 3 nm to about 6 nm to about 30 nm, the size of the grains 160_g may be greater than or equal to the thickness of the dielectric layer 160.

In some embodiments, as the dielectric layer 160 includes grains 160_g. Each of the grains 160_g has a size between about 3 nm and about 30 nm, the permittivity of the dielectric layer 160 may increase than when the dielectric layer 160 includes grains each having the size of less than about 3 nm. When the size of the grain increases, the amount of current leaking through a grain boundary is reduced, and thus the permittivity of the dielectric layer 160 may be increased. As the permittivity of the dielectric layer 160 increases, the capacitance of a capacitor CP0 may be increased.

Thus, according to embodiments, as the dielectric layer 160 includes the grains 160_g each having the size between about 3 nm and about 30 nm, the permittivity of the dielectric layer 160 may be increased. For example, as the capacitor CP0 includes the dielectric layer 160 including the grains 160_g each having the size between about 3 nm and about 30 nm, the capacitance of the capacitor CP0 may be increased. That is, according to embodiments, the semiconductor device 100 having the capacitor CP0 with the increased capacitance may be provided. That is, according to embodiments, the semiconductor device 100 having the capacitor CP0 with the increased performance and reliability may be provided.

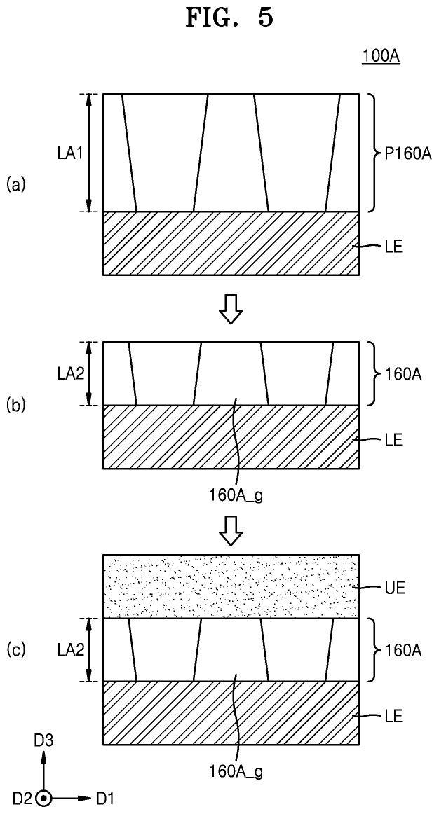

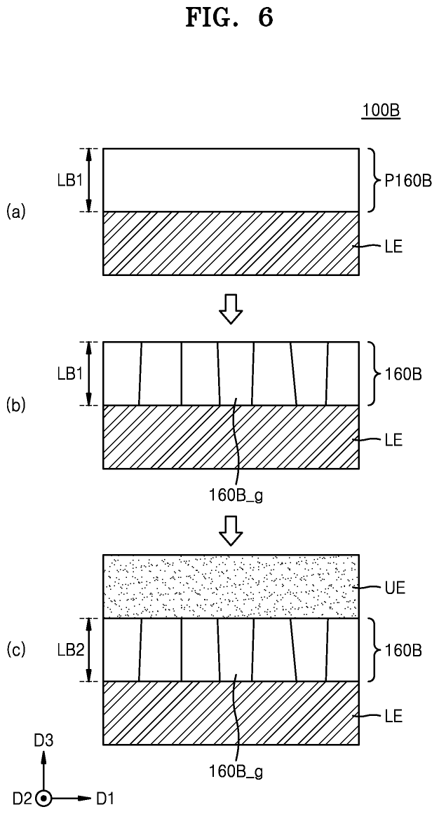

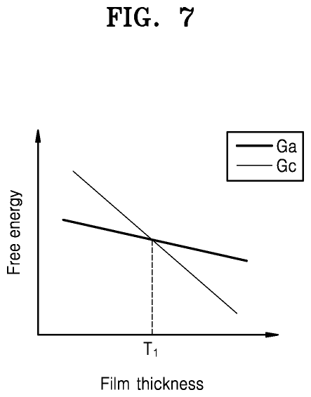

FIGS. 5 and 6 illustrate a semiconductor device according to embodiments. Specifically, FIG. 5 includes views for describing a procedure of forming a dielectric layer 160A of a semiconductor device 100A according to embodiments. Specifically, FIG. 6 includes views for describing a procedure of forming a dielectric layer 160B of a semiconductor device 100B by comparing the semiconductor device 100B with the semiconductor device 100A. FIG. 7 is a graph illustrating free energy according to thicknesses of a crystalline thin layer and an amorphous thin layer so as to describe a semiconductor device according to embodiments.

A semiconductor device includes a lower electrode disposed on a substrate; a dielectric layer covering the lower electrode; and an upper electrode spaced apart from the lower electrode, wherein the dielectric layer is disposed between the upper electrode and the lower electrode. The dielectric layer is deposited to an initial thickness that is greater than 6 nm and less than or equal to 15 nm and is etched to a final thickness that is less than or equal to 6 nm.

Referring to FIG. 5, the dielectric layer 160A of the semiconductor device 100A may be formed. Specifically, as shown in (a) of FIG. 5, a pre-dielectric layer P160A may be deposited on the lower electrode LE. An initial thickness LA1 of the pre-dielectric layer P160A deposited on the lower electrode LE may be greater than 6 nm. Specifically, the initial thickness LA1 of the pre-dielectric layer P160A may be greater than 6 nm and less than or equal to 15 nm. The grain size of the pre-dielectric layer P160A having the initial thickness LA1 that is greater than 6 nm and less than or equal to 15 nm may be about 3 nm to about 30 nm.

Subsequently, as shown in (b) of FIG. 5, the pre-dielectric layer P160A may be etched to a target thickness LA2 so that the dielectric layer 160A may be formed. The target thickness LA2 of the dielectric layer 160A may be less than the thickness LA1 of the pre-dielectric layer P160A. Specifically, the target thickness LA2 of the dielectric layer 160A may be less than or equal to 6 nm. Subsequently, as shown in (c) of FIG. 5, the upper electrode UE may be disposed on the dielectric layer 160A having the target thickness LA2 that is less than the initial thickness LA1.

Referring to FIG. 6, a dielectric layer 160B of the semiconductor device 100B according to a comparative example may be formed. Specifically, as shown in (a) of FIG. 6, a pre-dielectric layer P160B may be deposited on the lower electrode LE. An initial thickness LB1 of the pre-dielectric layer P160B deposited on the lower electrode LE may be less than or equal to 6 nm.

Subsequently, the pre-dielectric layer P160B may be crystallized, as shown in (b) of FIG. 6. The grain size of the pre-dielectric layer P160B having the initial thickness LB1 that is less than or equal to 6 nm may be less than about 3 nm. Subsequently, as shown in (c) of FIG. 6, the upper electrode UE may be disposed on the dielectric layer 160B having the same target thickness LB2 as the initial thickness LB1.

The dielectric layer 160A of the semiconductor device 100A according to the embodiments described above with reference to FIG. 5 may include grains 160A_g each having the size between about 3 nm and about 30 nm by depositing the pre-dielectric layer P160A to the initial thickness LA1 greater than the target thickness LA2. According to some embodiments, the dielectric layer 160B of the semiconductor device 100B according to the comparative example described with reference to FIG. 6 may include grains 160B_g each having the size that is less than about 3 nm by depositing the pre-dielectric layer P160B to the target thickness LB1. A relationship between an initial thickness LA1 and the grains 160A_g of the pre-dielectric layer P160A of the semiconductor device 100A will be described in detail below with reference to FIG. 7.

FIG. 7 shows a relationship Gc between the thickness of a crystalline thin layer and free energy, and a relationship Ga between the thickness of an amorphous thin layer and free energy. Referring to FIG. 7, as the thickness of the thin layer increases the free energy stabilizing both the crystalline and amorphous thin layers may decrease.

In some examples, when the thickness of the thin layer is less than T1, the free energy of the amorphous thin layer is lower than the free energy of the crystalline thin layer, so that an amorphous thin layer may be formed. In this case, a high-temperature crystallization process, for example, heat treatment, may be required to crystallize the amorphous thin layer.

In some examples, when the thickness of the thin layer is greater than T₁, the free energy of the crystalline thin layer is lower than the free energy of the amorphous thin layer, so that a crystalline thin layer may be formed. In this case, a high-temperature crystallization process for crystallizing the amorphous thin layer may not be required, or a sufficient crystalline thin layer may be formed even with relatively low-temperature heat treatment. For example, the low-temperature treatment may use a temperature less than 450° C. In addition, the size of the grains may increase when the thickness of the thin layer is less than T₁.

For example, according to the embodiment and the comparative example of the embodiments of the present disclosure illustrated in FIGS. 5 and 6, when a pre-dielectric layer P160A is deposited to an initial thickness LA1 that is greater than 6 nm, a dielectric layer 160A including grains 160 A_g each having a size between about 3 nm and about 30 nm, which is increased compared to when the pre-dielectric layer P160B is deposited to the initial thickness LB1 that is less than or equal to 6 nm, may be formed.

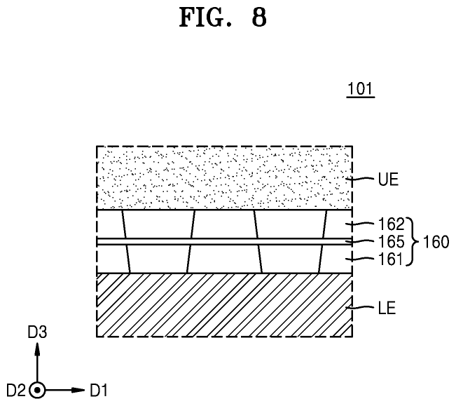

FIG. 8 is a detailed cross-sectional view for describing a semiconductor device 101 according to embodiments. Specifically, FIG. 8 corresponds to a detailed cross-sectional view of a region EX1 of FIG. 3, and is a detailed view of an area of the semiconductor device 101.

In some embodiments, the dielectric layer 160 may include multiple layers in which a plurality of material layers including different materials are stacked. For example, the dielectric layer 160 may include a first dielectric layer 161 contacting the lower electrode LE, and a second dielectric layer 162 on the first dielectric layer 161.

In some embodiments, the first dielectric layer 161 may include a ferroelectric material layer, a semi-ferroelectric material layer, or a combination thereof. In some embodiments, the first dielectric layer 161 may include a single layer in which a ferroelectric material and a semi-ferroelectric material are ununiformly mixed with each other. For example, dielectric layer 161 may have one single layer including ferroelectric and semi-ferroelectric materials, and these ferroelectric and semi-ferroelectric materials are not mixed evenly in the single layer. In some embodiments, the first dielectric layer 161 may include a single layer including a ferroelectric material. In some embodiments, the first dielectric layer 161 may include a single layer including a semi-ferroelectric material. The second dielectric layer 162 may include a paradielectric layer.

In some embodiments, the first dielectric layer 161 may include HfZrO₂, ZrO₂, PbTiO₃, AgNbO₃ or a combination thereof. The second dielectric layer 162 may include HfO₂, ZrO₂, TiO₂, Ta₂O₃, VO₂, AlO₂, SiO₂, SrTiO₃ BaTiO₃, BiFcO₃ or a combination thereof.

In some embodiments, the dielectric layer 160 may further include an insertion layer 165 inserted between multiple layers. Specifically, the insertion layer 165 may be disposed between the first dielectric layer 161 and the second dielectric layer 162.

In some embodiments, the insertion layer 165 may include at least one selected from the group consisting of aluminum oxide (Al₂O₃), yttrium oxide (Y₂O₃), niobium oxide (Nb₂O₅), vanadium oxide (V₂O⁵), and lanthanum oxide (La₂O₃). In some embodiments, the insertion layer 165 may include at least one selected from the group consisting of Ta, antimony (Sb), molybdenum (Mo), Co, Nb, copper (Cu), nickel (Ni), vanadium (V), W, an oxide thereof, and a nitride thereof.

In some embodiments, the thickness of the dielectric layer 160 may be greater than 0 nm and less than or equal to 6 nm. For example, when the dielectric layer 160 further includes the insertion layer 165 between the first dielectric layer 161 and the second dielectric layer 162, the sum of the thickness of the first dielectric layer 161, the thickness of the insertion layer 165, and the thickness of the second dielectric layer 162 may be greater than 0 nm and less than or equal to 6 nm. In some embodiments, the thickness of the first dielectric layer 161 and the thickness of the second dielectric layer 161 may be greater than 0 nm and less than or equal to 3 nm. In other embodiments, the thickness of the first dielectric layer 161 or the thickness of the second dielectric layer 162 may be greater than 3 nm and less than 6 nm. However, embodiments are not limited thereto.

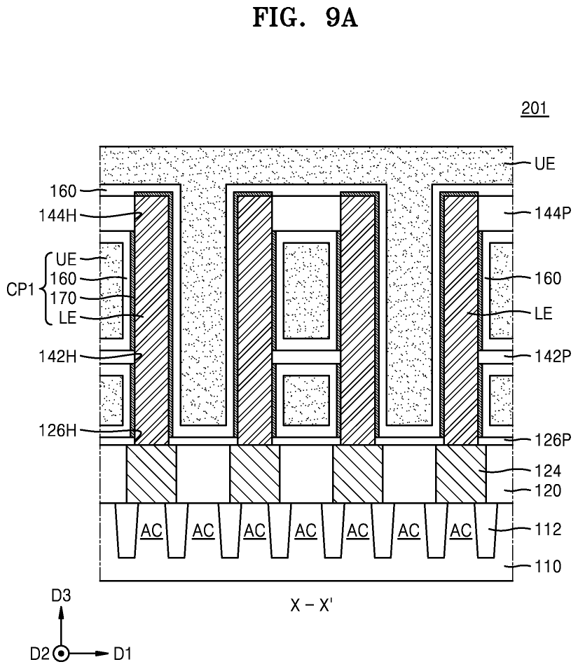

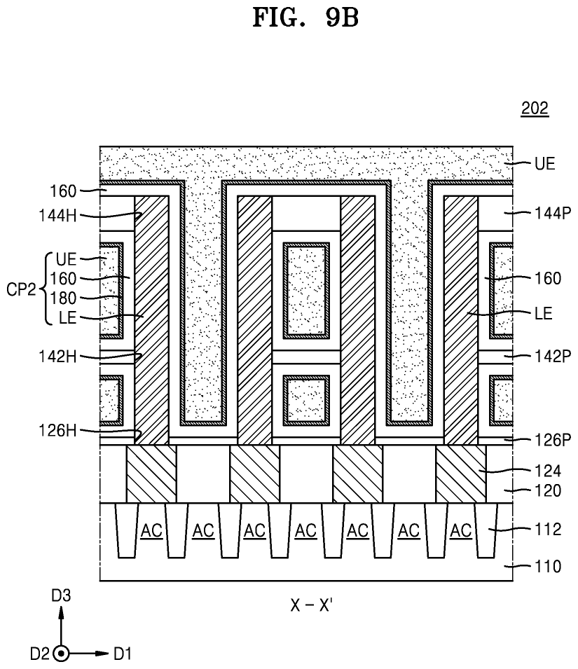

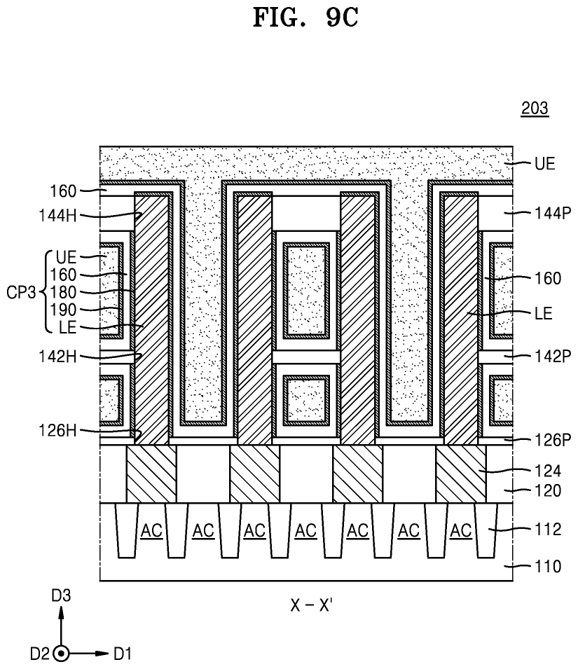

FIGS. 9A and 9C illustrate semiconductor devices 201, 202, and 203 according to embodiments.

Referring to FIG. 9A, the semiconductor device 201 may include a plurality of capacitors CP1. Each of the plurality of capacitors CP1 may include a lower electrode LE extending in the direction D3 perpendicular to an upper surface of the substrate 110, supporters 142P and 144P surrounding a sidewall of the lower electrode LE and supporting the lower electrode LE, a dielectric layer 160 disposed on the lower electrode LE and the supporters 142P and 144P, an upper electrode UE covering the dielectric layer 160 and spaced apart from the lower electrode LE. In some cases, the dielectric layer 160 may be disposed between the dielectric layer 170 and the lower electrode LE. In some cases, a lower interface layer 170 may be disposed between the dielectric layer 160 and the lower electrode LE.

In some embodiments, the lower interface layer 170 may include at least one selected from the group consisting of Ta, Sb, Mo, Co, Nb, Cu, Ni, V, W, an oxide thereof, and a nitride thereof. The lower interface layer 170 may include a lower doping layer and/or a lower seed layer. The total thickness of the lower interface layer 170 may be less than or equal to 1.5 nm. For example, when the lower interface layer 170 includes the lower doping layer and the lower seed layer, the sum of thicknesses of the lower doping layer and the lower seed layer may be less than or equal to 1.5 nm.

In some embodiments, the lower interface layer 170 may be disposed on the lower electrode LE to serve to improve resistance by supplying a carrier when the lower electrode LE is oxidized. For example, the lower interface layer 170 may be disposed on the lower electrode LE to include a lower doping layer for increasing resistance by supplying a carrier when the lower electrode LE is oxidized. In some embodiments, the lower interfacial layer 170 may be disposed between the lower electrode LE and the dielectric layer 160 to serve to mitigate crystalline mismatch between the lower electrode LE and the dielectric layer 160. For example, the lower interface layer 170 may include a lower seed layer disposed between the lower electrode LE and the dielectric layer 160 to enhance the crystallinity of the dielectric layer 160.

Referring to FIG. 9B, the semiconductor device 202 may include a plurality of capacitors CP2. Each of the plurality of capacitors CP2 may include a lower electrode LE extending in the direction D3 perpendicular to an upper surface of the substrate 110, supporters 142P and 144P surrounding a sidewall of the lower electrode LE and supporting the lower electrode LE, a dielectric layer 160 disposed on the lower electrode LE and the supporters 142P and 144P, an upper electrode UE covering the dielectric layer 160 and spaced apart from the lower electrode LE. In some cases, the dielectric layer 160 may be disposed between the dielectric layer 160 and the lower electrode LE. In some cases, an upper interface layer 180 may be disposed between the dielectric layer 160 and the upper electrode UE.

In some embodiments, the upper interface layer 180 may include at least one selected from the group consisting of Ta, Sb, Mo, Co, Nb, Cu, Ni, V, W, an oxide thereof, and a nitride thereof. The upper interface layer 180 may include an upper doping layer and/or an upper seed layer. The total thickness of the upper interface layer 180 may be less than or equal to 1.5 nm. For example, when the upper interface layer 180 includes the upper doping layer and the upper seed layer, the sum of thicknesses of the lower doping layer and the lower seed layer may be less than or equal to 1.5 nm.

In some embodiments, the upper interface layer 180 may be disposed on the upper electrode UE to serve to improve resistance by supplying a carrier when the upper interface layer 180 is oxidized. For example, the upper interface layer 170 may be disposed on the upper electrode UE to include a lower doping layer for increasing resistance by supplying a carrier when the upper electrode UE is oxidized. In some embodiments, the upper interfacial layer 180 may be disposed between the upper electrode UE and the dielectric layer 160 to serve to mitigate crystalline mismatch between the upper electrode UE and the dielectric layer 160. For example, the upper interface layer 180 may include a lower seed layer disposed between the upper electrode UE and the dielectric layer 160 to enhance the crystallinity of the dielectric layer 160. Referring to FIG. 9C, semiconductor device 203 may include a plurality of capacitors CP3. Each of the plurality of capacitors CP3 may include a lower electrode LE extending in the direction D3 perpendicular to an upper surface of the substrate 110. Supporters 142P and 144P may be provided surrounding a sidewall of the lower electrode LE and support the sidewall. A dielectric layer 160 may be disposed on both the lower electrode LE and the supporters 142P and 144P. The upper electrode UE may cover the dielectric layer 160 and spaced apart from the lower electrode LE, where the dielectric layer 160 is disposed between the dielectric layer 160 and the lower electrode LE, a lower interface layer 170 is disposed between the dielectric layer 160 and the lower electrode LE, and an upper interface layer 180 is disposed between the dielectric layer 160 and the upper electrode UE.

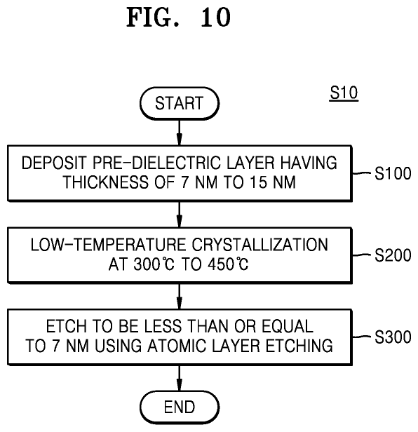

FIGS. 10 through 14 are flowcharts for describing a method of manufacturing a semiconductor device according to embodiments. Specifically, FIGS. 10 through 14 are flowcharts for describing a method (S10) of manufacturing a dielectric layer of a semiconductor device.

Referring to FIG. 10, the method (S10) of manufacturing the dielectric layer of a semiconductor device may include a pre-dielectric layer deposition operation (S100), a low-temperature crystallization operation (S200), and an atomic layer etching operation (S300).

In some examples, a pre-dielectric layer having a thickness that is greater than about 6 nm and less than or equal to 15 nm may be deposited through a pre-dielectric layer deposition operation (S100). The pre-dielectric layer deposition operation (S100) may be performed by using atomic layer deposition (ALD) or chemical vapor deposition (CVD) at the temperature of about 200° C. to about 400° C. O₃, H₂O, O₂, and H₂O₂ may be used as a reactant.

In some examples, crystallizing of the pre-dielectric layer may be performed through the low-temperature crystallization operation (S200). The low-temperature crystallization operation (S200) may be performed at the temperature of about 300° C. to about 450° C. As described above, by depositing a pre-dielectric layer having a thickness of greater than about 6 nm and less than or equal to about 15 nm in order to manufacture the dielectric layer of the embodiments of the present disclosure, the high-temperature crystallization operation involved in depositing the dielectric layer to a thickness of about 6 nm or less, for example, the high-temperature crystallization operation of about 350° C. to about 700° C. may not be required. Grains each having the size between about 3 nm and about 30 nm may be generated through the low-temperature crystallization operation (S200).

In some embodiments, a pre-dielectric layer having a sufficiently thick thickness may be deposited in the pre-dielectric layer deposition operation (S100) described above, and when the free energy required for crystallization is sufficiently lowered, a separate low-temperature crystallization operation (S200) may not be further performed. For example, when a separate low-temperature crystallization operation (S200) is not further performed, the pre-dielectric layer may include grains each having the size between about 3 nm and about 30 nm.

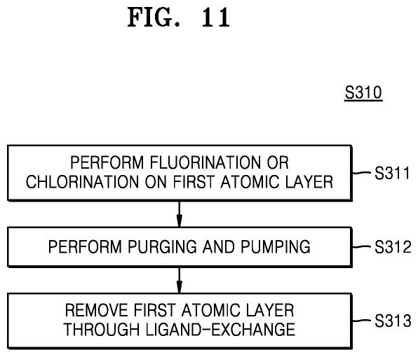

In some examples, the pre-dielectric layer having a thickness that is greater than about 6 nm and less than or equal to about 15 nm and includes grains each having the size between about 3 nm and about 30 nm may be etched to the thickness of 6 nm or less through the atomic layer etching operation (S300), thereby manufacturing a dielectric layer. Hereinafter, the atomic layer etching operation (S300) will be described in detail with reference to FIGS. 11 through 14. In some examples, the dielectric layer is deposited to an initial thickness that is greater than 6 nm and less than or equal to 15 nm and is etched to a final thickness that is less than or equal to 6 nm.

Referring to FIG. 11, the atomic layer etching operation (S300) may include etching a first atomic layer (S310). The etching of the first atomic layer (S310) may include an operation of performing fluorination or chlorination on the first atomic layer (S311), a purging and pumping operation (S312), and an operation of removing the first atomic layer through ligand-exchange (S313).

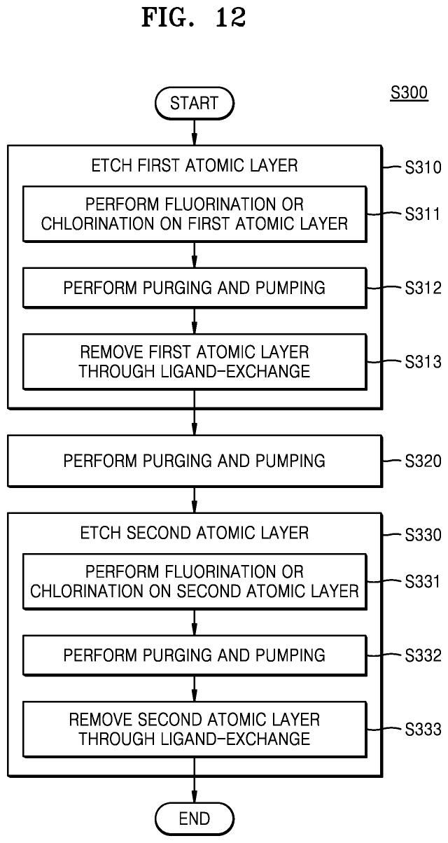

Referring to FIG. 12, the atomic etching operation (S300) may include etching the first atomic layer (S310) and etching a second atomic layer (S330). Specifically, after the etching of the first atomic layer (S310), the etching of the second atomic layer (S330) may be further performed.

After the etching of the first atomic layer (S310) is performed, the purging and pumping operation (S320) may be performed. Subsequent to that, the etching of the second atomic layer (S330) may be performed. That is, after the first atomic layer is etched, the purging and pumping operation (S320) may be performed so that an operation of removing reaction by-products on the atomic layer may be performed. The purging and pumping operation (S320) may be performed between the etching of the first atomic layer (S310) and the etching of the second atomic layer (S330) so that a process performance ability of the etching of the second atomic layer (S330) may be increased.

Specifically, the etching of the second atomic layer (S330) may include the fluorinating or chlorinating of the second atomic layer (S331), the purging and pumping operation (S332), and the removing of the second atomic layer through ligand-exchange (S333).

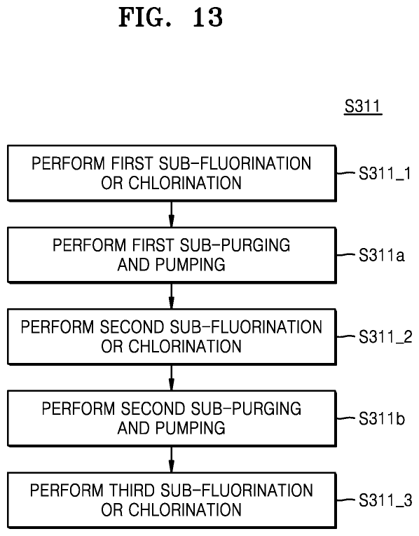

Referring to FIG. 13, the performing of fluorination or chlorination on the first atomic layer (S311) may be performed through a plurality of divided operations. For example, the performing of fluorination or chlorination on the first atomic layer (S311) may include a first sub-fluorination or chlorination operation (S311_1), a second sub-fluorination or chlorination operation (S311_2), and a third sub-fluorination or chlorination operation (S311_3). For example, the performing of fluorination or chlorination on the first atomic layer (S311) may be broken into three stages. In some other embodiments, the performing of fluorination or chlorination on the first atomic layer (S311) may be performed through two or four or more divided operations.

In some embodiments, a purging and pumping operation may be performed between each of the plurality of divided fluorination or chlorination operations. For example, the first sub-purging and pumping operation (S311a) may be performed after the first sub-fluorination or chlorination operation (S311_1) is performed. For example, a second sub-purging and pumping operation (S311b) may be performed after the second sub-fluorination or chlorination operation (S311_2) is performed. Thereafter, a third sub-fluorination or chlorination operation (S311_3) may be performed.

In some embodiments, the purging and pumping operation is performed between each of a plurality of divided fluorination or chlorination operations so that reaction by-products generated in the fluorination or chlorination operation may be removed. In particular, the reaction by-products generated in the fluorination or chlorination operation may be more frequently removed so that a process performance ability of the fluorination or chlorination operation to be performed later may be increased. For example, the first sub-purging and pumping operation (S311a) may be performed after the first sub-fluorination or chlorination operation (S311_1) to remove the reaction by-products generated in the first sub-fluorination or chlorination operation (S311_1), thereby increasing the process performance ability of the second sub-fluorination or chlorination operation(S311_2) to be performed later.

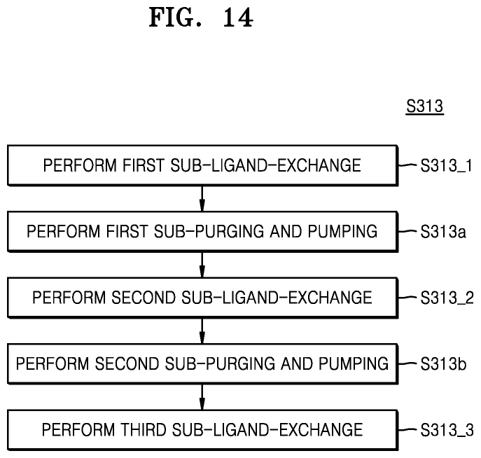

Referring to FIG. 14, the removing of the first atomic layer (S313) through ligand-exchange may be performed through a plurality of divided operations. For example, the removing of the first atomic layer through ligand-exchange (S313) may include a first sub-ligand exchange operation (S313_1), a second sub-ligand exchange operation (S313_2), and a third sub-ligand exchange operation (S313_3). For example, the removing of the first atomic layer through ligand-exchange (S313) may be performed through three divided operations. In some other embodiments, the removing of the first atomic layer through ligand-exchange (S313) may be performed through two or four more divided operations.

In some embodiments, a purging and pumping operation may be performed between each of the plurality of divided ligand-exchange operations. For example, a first sub-purging and pumping operation (S313a) may be performed after the first sub-ligand exchange operation (S313_1) is performed. For example, a second sub-purging and pumping operation (S313b) may be performed after the second sub-ligand exchange operation (S313_2) is performed. Thereafter, a third sub-ligand exchange operation (S313_3) may be performed.

In some embodiments, the purging and pumping operation is performed between each of a plurality of divided ligand-exchange operations so that reaction by-products generated in the ligand-exchange operation may be removed. In particular, the reaction by-products generated in the ligand-exchange operation may be more frequently removed so that a process performance ability of the ligand-exchange operation to be performed later may be increased. For example, after the first sub-ligand exchange operation (S313_1) is performed, the first sub-purging and pumping operation (S313a) may be performed to remove residual by-products in the first sub-ligand exchange operation (S313_1), and thus, the process performance ability of the second sub-ligand exchange operation (S313_2) to be performed later may be increased.

FIGS. 15A through 15G are cross-sectional views for describing a method of manufacturing a semiconductor device according to embodiments. In FIGS. 15A through 15G, the same reference numerals as those in FIGS. 1 through 4 represent the same elements, and repeated descriptions thereof will be omitted.

According to some embodiments, a semiconductor device includes an active region defined by a device isolation layer in a substrate, word lines extending in a first horizontal direction, bit lines extending in a second horizontal direction perpendicular to the first horizontal direction, and a capacitor structure electrically connected to the active region at a vertical level that is higher than the bit lines. In some cases, the capacitor structure comprises a lower electrode extending in a vertical direction perpendicular to the first horizontal direction and the second horizontal direction, a dielectric layer covering the lower electrode, and an upper electrode spaced apart from the lower electrode, In some cases, the dielectric layer is disposed between the upper electrode and the lower electrode. In some cases, a thickness of the dielectric layer is less than or equal to 6 nm. In some cases, a grain size in the dielectric layer is between 3 nm and 15 nm.

Referring to FIG. 15A, a lower structure 120 and a conductive region 124 connected to an active region AC by passing through the lower structure 120 may be formed on a substrate 110 in which the active region AC is defined by a device isolation layer 112. For example, the active region AC on the substrate 110 is defined by the device isolation layer 112 when the device isolation layer 112 outlines the boundaries of the active region AC, indicating where the active region AC is located or how it is shaped on the substrate 110. Thereafter, an insulating layer 126 covering the lower structure 120 and the conductive region 124 may be formed.

The insulating layer 126 may be used as an etch stopper in a subsequent process. The insulating layer 126 may include an insulating material having an etch selectivity with respect to the lower structure 120. In some embodiments, the insulating pattern 126 may include silicon nitride (SiN), silicon carbon nitride (SiCN), silicon boron nitride (SiBN), or a combination thereof.

Referring to FIG. 15B, a mold structure MST may be formed on the insulating layer 126. The mold structure MST may include a plurality of mold layers and a plurality of support layers. For example, the mold structure MST may include a first mold layer 132, a lower supporter layer 142, a second mold layer 134, and an upper supporter layer 144, where the first mold layer 132, the lower supporter layer 142, the second mold layer 134, and the upper supporter layer 144 are sequentially stacked on the insulating layer 126. According to some embodiments, each of the first mold layer 132 and the second mold layer 134 may have a comparatively high etching rate with respect to an etchant including ammonium fluoride (NH₄F), hydrofluoric acid (HF) and water, and each of the first mold layer 132 and the second mold layer 134 may include a material that may be removed by a lift-off process using the etchant. In some embodiments, each of the first mold layer 132 and the second mold layer 134 may include an oxide layer, a nitride layer, or a combination thereof. For example, the first mold layer 132 may include a boron phosphor silicate glass (BPSG) layer. The BPSG layer may include at least one of a first portion in which the concentration of a dopant boron (B) is changed in the thickness direction of the BPSG layer, and a second portion in which the concentration of a dopant phosphorus (P) is changed in the thickness direction of the BPSG layer. The second mold layer 134 may include a multiple insulating layer in which a silicon oxide layer and a silicon nitride layer that are comparatively thin are alternately repeatedly stacked a plurality of times one by one, or a silicon nitride layer. However, the material of each of the first mold layer 132 and the second mold layer 134 is not limited thereto, and various modifications and changes may be performed within the scope of the technical spirit of the embodiments of the present disclosure. In addition, the stacking order of the mold structure (MST) is not limited to that illustrated in FIG. 15B, and multiple modifications and changes are performed within the scope of the technical idea of the embodiments of the present disclosure.

Each of the lower supporter layer 142 and the upper supporter layer 144 may include SiN, SiCN, SiBN, or a combination thereof. In some embodiments, the lower supporter layer 142 and the upper supporter layer 144 may include the same material. In another embodiment, the lower supporter layer 142 and the upper supporter layer 144 may include different materials. In an example, each of the lower supporter layer 142 and the upper supporter layer 144 may include SiCN. In another example, the lower supporter layer 142 may include SiCN, and the upper supporter layer 144 may include boron-containing silicon nitride. However, the material of each of the lower supporter layer 142 and the upper supporter layer 144 is not limited thereto, and multiple modifications and changes may be performed within the scope of the technical spirit of the embodiments of the present disclosure.

Referring to FIG. 15C, after a mask pattern MP is formed on the mold structure MST in the resultant material of FIG. 15B, the mold structure MST may be anisotropically etched by using the mask pattern MP as an etching mask and the insulating layer 126 as an etch stopper, thereby forming a mold structure pattern MSP restricting a plurality of holes BH. The mold structure pattern MSP may include a first mold pattern 132P, a lower supporter 142P, a second mold pattern 134P, and an upper supporter 244P.

The mask pattern MP may include a nitride layer, an oxide layer, a polysilicon layer, a photoresist layer, or a combination thereof.

A process of forming a plurality of holes BH may further include a process of wet-treating a result obtained by anisotropically etching the mold structure MST. Wet-treating refers to a process in which a material or substrate is subjected to a treatment using a liquid medium, often involving chemical reactions or interactions. For example, wet treating may be used to achieve desired changes or results on a surface or material by using specific liquid chemicals or solutions. Wet-treat may include etching processes. While a process of anisotropically etching the mold structure MST and wet-treating a result obtained by anisotropically etching is performed, a portion of the insulating layer 126 may also be etched so that an insulating pattern 126P having a plurality of openings 126H exposing a plurality of conductive regions 124 may be obtained. In an example process of wet-treating the result obtained by anisotropically etching the mold structure MST, an etchant including a diluted sulfuric acid peroxide (DSP) solution may be used. However, embodiments are not limited thereto.

In the mold structure pattern MSP, a plurality of holes 142H that is a part of the plurality of holes BH may be formed in the lower supporter 142P, and a plurality of holes 144H that is a part of the plurality of holes BH may be formed in the upper supporter 144P.

Referring to FIG. 15D, the mask pattern MP may be removed from the result of FIG. 15C, and a lower electrode LE filling the plurality of holes BH may be formed.

In some embodiments, in order to form the lower electrode LE, while the plurality of holes BH may be filled in the result of FIG. 9D, a conductive layer covering the upper surface of the upper supporter 144P may be formed. In order to form the conductive layer, a chemical vapor deposition (CVD) process, a plasma increased CVD (PECVD) process, a metal organic CVD (MOCVD) process, or an atomic layer deposition (ALD) process may be used. Thereafter, a part of the conductive layer may be removed using an etch-back process or a chemical mechanical polishing (CMP) process, so that the upper surface of the upper supporter 144P may be exposed.

Referring to FIG. 15E, after a part of the upper supporter 144P is removed from the result of FIG. 15D to form a plurality of upper holes UH, the second mold pattern 134P may be wet-removed through the plurality of upper holes UH. Thereafter, after a part of the lower supporter 142P exposed through the plurality of upper holes UH is removed to form a plurality of lower holes LH, the first mold pattern 132P may be wet-removed through the plurality of lower holes LH to expose the upper surface of the insulating pattern 126P. After the first mold pattern 132P and the second mold pattern 134P are removed, sidewalls of the plurality of lower electrodes LE may be exposed.

In some embodiments, an etchant including NH₄F, HF and water may be used to wet-remove the second mold pattern 134P and the first mold pattern 132P. However, embodiments of the present disclosure are not limited thereto.

Referring to FIGS. 15F and 15G, a process of forming the dielectric layer 160 covering the lower electrode LE exposed from the result of FIG. 15E may be performed.

Specifically, as shown in FIG. 15F, a pre-dielectric layer P160 may be deposited on the lower electrode LE. As described above with reference to FIG. 10, the pre-dielectric layer P160 may be deposited using a PECVD or MOCVD process in addition to ALD and CVD, at the temperature between about 200° C. and about 400° C. The deposition thickness D2 of the pre-dielectric layer P160 may be greater than about 6 nm and less than or equal to about 15 nm. The deposition thickness of the pre-dielectric layer P160 may be less than or equal to ½ of a separation distance D1 between a plurality of lower electrodes LE. For example, the maximum deposition thickness of the pre-dielectric layer P160 may be ½ of the separation distance D1 between a plurality of lower electrodes LE. For example, when the separation distance D1 between the plurality of lower electrodes LE is 30 nm, the maximum deposition thickness of the pre-dielectric layer P160 may be 15 nm.

The pre-dielectric layer P160 may cover exposed surfaces of each of the lower support 142P and the upper supporter 144P and exposed surfaces of the insulating pattern 126P in addition to the sidewalls of the lower electrodes LE.

After a deposition process of the pre-dielectric layer P160 covering the lower electrodes LE is performed, a low-temperature crystallization process may be performed. In particular, In some embodiments in which the pre-dielectric layer P160 is deposited to a thickness that is greater than about 6 nm and less than or equal to about 15 nm, the crystallization process may be performed at the temperature of about 300° C. to about 450° C. Grains each having a size between about 3 nm and about 30 nm may be generated through the low-temperature crystallization operation. For example, grains each having a size of about 3 nm to about 15 nm may be generated through the low-temperature crystallization operation. When the grain size is about 3 nm to about 15 nm, grains each having a size that is less than or equal to the maximum thickness of the pre-dielectric layer P160 may be generated. When the grain size is about 15 nm to about 30 nm, grains each having a size that is greater than or equal to the maximum thickness of the pre-dielectric layer P160 may be generated.

Thereafter, as shown in FIG. 15G, a dielectric layer 160 may be formed in the pre-dielectric layer P160 by performing an atomic layer etching process described with reference to FIGS. 10 through 14. The final thickness of the dielectric layer 160 may be less than or equal to about 6 nm.

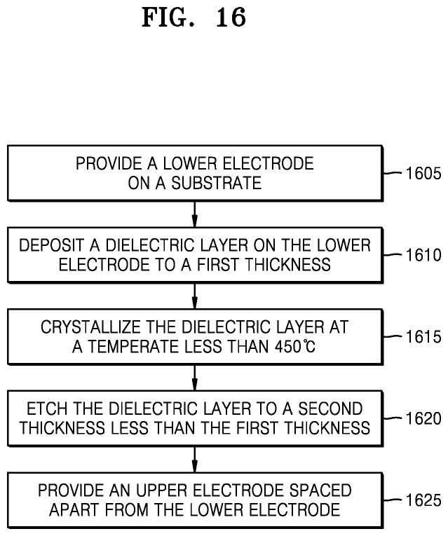

Referring to FIG. 16, a method of manufacturing a semiconductor device may include providing a lower electrode on a substrate, depositing a dielectric layer on the lower electrode to a first thickness, crystallizing the dielectric layer at a temperature less than 450° C., etching the dielectric layer to a second thickness less than the first thickness, and providing an upper electrode spaced apart from the lower electrode, wherein the dielectric layer is disposed between the upper electrode and the lower electrode.

Step 1605 involves providing a lower electrode on a substrate. In some examples, depositing a dielectric layer on the lower electrode to a first thickness includes placing or forming a conductive layer, for example, a lower electrode, directly onto the substrate. The substrate may be made of various materials, such as silicon, sapphire, or other semiconductive or insulating materials.

Step 1610 involves depositing a dielectric layer on the lower electrode to a first thickness. Subsequent to providing a lower electrode on a substrate, a dielectric layer may be deposited over the lower electrode up to a predetermined thickness. Dielectric materials may be electrical insulators that can be polarized by an applied electric field. The dielectric layer may isolate electrical components.

Step 1615 involves crystallizing the dielectric layer at a temperature less than 450° C. After depositing a dielectric layer on the lower electrode to a first thickness, the dielectric layer undergoes a crystallization process. In some examples, this crystallization process involves heating the layer to a temperature below 450° C. In some examples, at this controlled temperature, the dielectric material undergoes a phase change, becoming more ordered or crystalline, therefore improving its dielectric properties.

Step 1620 involves etching the dielectric layer to a second thickness less than the first thickness. After crystallizing the dielectric layer at a temperature less than 450° C., a part of the dielectric layer may be removed or etched away until it reaches a desired second thickness. This etching process may be used for precise control over the layer's dimensions.

Step 1625 involves providing an upper electrode spaced apart from the lower electrode, wherein the dielectric layer is disposed between the upper electrode and the lower electrode. After etching the dielectric layer to a second thickness less than the first thickness, an upper electrode spaced apart from the lower electrode may be provided, and the dielectric layer may be disposed between the upper electrode and the lower electrode. In some examples, this step involves introducing an upper electrode that is placed parallel to and spaced apart from the lower electrode. In some examples, the dielectric layer fills the gap between the two electrodes.

In some examples, the first thickness is greater than 6 nm and the second thickness is less than 6 nm.

While the embodiments of the present disclosure have been particularly shown and described with reference to embodiments thereof, it will be understood that multiple changes in form and details may be made therein without departing from the spirit and scope of the following claims.

What is claimed is:

1. A semiconductor device comprising:
a lower electrode disposed on a substrate;
a dielectric layer covering the lower electrode; and
an upper electrode spaced apart from the lower electrode, wherein the dielectric layer is disposed between the upper electrode and the lower electrode,
wherein a thickness of the dielectric layer is less than or equal to 6 nm, and
a grain size in the dielectric layer is between 3 nm and 30 nm.

2. The semiconductor device of claim 1, wherein the dielectric layer comprises at least one selected from fluorine (F) and chloride (Cl), and
a content of at least one selected from F and Cl in the dielectric layer is between 0.01 at % and 15 at %.

3. The semiconductor device of claim 1, further comprising at least one of a lower interface layer between the dielectric layer and the lower electrode, and an upper interface layer between the dielectric layer and the upper electrode, wherein
a thickness of each of the lower interface layer and the upper interface layer is less than or equal to 1.5 nm.

4. The semiconductor device of claim 3, wherein each of the lower interface layer and the upper interface layer comprises at least one selected from tantalum (Ta), antimony (Sb), molybdenum (Mo), cobalt (Co), niobium (Nb), copper (Cu), nickel (Ni), vanadium (V), tungsten (W), an oxide thereof, and a nitride thereof.

5. The semiconductor device of claim 1, wherein the dielectric layer is a multiple layer including a first dielectric layer and a second dielectric layer, which are stacked on each other.

6. The semiconductor device of claim 5, wherein the dielectric layer further comprises an insertion layer which is between the first dielectric layer and the second dielectric layer, and which includes a different material from materials for forming the first dielectric layer and the second dielectric layer.

7. The semiconductor device of claim 6, wherein the insertion layer comprises at least one selected from aluminum oxide (Al₂O₃), yttrium oxide (Y₂O₃), niobium oxide (Nb₂O₅), vanadium oxide (V₂O₅), and lanthanum oxide (La₂O₃).

8. The semiconductor device of claim 1, wherein the dielectric layer comprises at least one selected from zirconium oxide (ZrO₂), hafnium oxide (HfO₂), and titanium oxide (TiO₂).

9. A semiconductor device comprising:
a lower electrode disposed on a substrate;
a dielectric layer covering the lower electrode; and
an upper electrode spaced apart from the lower electrode, wherein the dielectric layer is disposed between the upper electrode and the lower electrode, wherein
the dielectric layer is deposited to an initial thickness that is greater than 6 nm and less than or equal to 15 nm and is etched to a final thickness that is less than or equal to 6 nm.

10. The semiconductor device of claim 9, wherein the dielectric layer is crystallized at a temperature between 300° C. and 450° C. after being deposited to a thickness that is greater than 6 nm and less than or equal to 15 nm.

11. The semiconductor device of claim 9, wherein a grain size in the dielectric layer is between 3 nm and 15 nm.

12. The semiconductor device of claim 9, wherein the dielectric layer is etched using atomic layer etching comprising:
performing at least one of fluorination and chlorination on a first atomic layer of the dielectric layer;
purging and pumping; and
performing ligand-exchange of removing the first atomic layer on which at least one selected from fluorination and chlorination is performed.

13. The semiconductor device of claim 12, wherein the atomic layer etching further comprises purging and pumping after the performing of ligand-exchange is performed, and
a cycle comprising performing at least one selected from fluorination and chlorination, first purging and pumping, performing ligand-exchange, and second purging and pumping is repeated.

14. The semiconductor device of claim 12, wherein the performing of at least one selected from fluorination and chlorination comprises:
performing at least one selected from first sub-fluorination and chlorination;
first sub-purging and pumping; and
performing at least one selected from second sub-fluorination and chlorination,
wherein the performing of ligand-exchange comprises:
performing first sub-ligand-exchange;
performing second sub-purging and pumping; and
performing second sub-ligand-exchange.

15. The semiconductor device of claim 9, wherein the dielectric layer comprises at least one selected from fluorine (F) and chloride (Cl), and
a content of at least one selected from F and Cl in the dielectric layer is between 0.01 at % and 15 at %.

16. A semiconductor device comprising:
an active region defined by a device isolation layer in a substrate;
word lines extending in a first horizontal direction;
bit lines extending in a second horizontal direction perpendicular to the first horizontal direction; and
a capacitor structure electrically connected to the active region at a vertical level that is higher than the bit lines, wherein the capacitor structure comprises:
a lower electrode extending in a vertical direction perpendicular to the first horizontal direction and the second horizontal direction;
a dielectric layer covering the lower electrode; and
an upper electrode spaced apart from the lower electrode, wherein the dielectric layer is disposed between the upper electrode and the lower electrode,
a thickness of the dielectric layer is less than or equal to 6 nm, and
a grain size in the dielectric layer is between 3 nm and 15 nm.

17. The semiconductor device of claim 16, wherein the dielectric layer is deposited to an initial thickness that is greater than 6 nm and less than or equal to 15 nm, is crystallized at a temperature between 300° C. and 450° C., and is etched to a final thickness that is less than or equal to 6 nm.

18. The semiconductor device of claim 17, wherein the atomic layer etching comprises:
performing at least one of fluorination and chlorination on a first atomic layer of the dielectric layer;
purging and pumping; and
performing ligand-exchange of removing the first atomic layer on which at least one selected from fluorination and chlorination is performed.

19. The semiconductor device of claim 18, wherein the performing of at least one selected from fluorination and chlorination comprises:
performing at least one selected from first sub-fluorination and chlorination;
first sub-purging and pumping; and
performing at least one selected from second sub-fluorination and chlorination, and
the performing of ligand-exchange comprises:
performing first sub-ligand-exchange;
performing second sub-purging and pumping; and
performing second sub-ligand-exchange.

20. The semiconductor device of claim 16, wherein the dielectric layer comprises at least one selected from fluorine (F) and chloride (Cl), and
a content of at least one selected from F and Cl in the dielectric layer is between 0.01 at % and 15 at %.
